(19) United States
(12) Patent Application Publication
(10) Pub. No.: US 2025/0151541 A1
(43) Pub. Date: May 8, 2025

(54) PHOTODIODE AND METHOD OF OPERATION

(71) Applicant: ams Semiconductors India Pvt. Ltd., Hyderabad, Telangana (IN)

(72) Inventors: Rajesh GUPTA, Chennai, Tamil Nadu (IN); Alberto SOZZANI, München (DE); Sameer BAVEJA, München (DE)

(21) Appl. No.: 18/835,403

(22) PCT Filed: Feb. 2, 2023
(86) PCT No.: PCT/IN2023/050099

§ 371 Date: Aug. 2, 2024

(30) Foreign Application Priority Data
Feb. 2, 2022 (IN) 202241005684

(51) Int. Cl. H10K 59/13; G01J 1/44

(52) U.S. Cl. CPC H10K 59/13; G01J 1/44; G01J 2001/446

(57) ABSTRACT

An island photodiode includes a semiconductor chip having one or more island photodiode regions and one or more carrier collection regions. The one or more island photodiode regions and the one or more carrier collection regions are located in a light receiving area of the semiconductor chip with the one or more of the carrier collection regions being arranged at least partially around each island photodiode region. The one or more carrier collection regions are electrically addressable separately from the one or more island photodiode regions.

### FIELD

The present disclosure relates to an island photodiode and an associated method of operation for use in ambient light sensing, proximity sensing and flicker detection applications and, in particular though not exclusively, to an island photodiode and an associated method of operation for use in an ambient light sensor located behind a display such as an OLED display.

### BACKGROUND

Modem consumer electronics, such as smartphones, increasingly implement a variety of optical sensors. For example, such sensors may include ambient light sensors, proximity sensors, sensors configured to detect flicker in ambient light, and the like.

Such optical sensors may be required to meet stringent requirements relating to accuracy, sensitivity and, in particular, signal-to-noise ratio.

For example, in some applications such as “behind-OLED” applications, optical sensors may need to operate at very low light levels, making accurate detection of incident light levels difficult to achieve.

Furthermore, implementing optical sensors that are capable of meeting stringent accuracy and sensitivity requirements, while also taking into account further requirements relating to cost, miniaturization, power limitations, and fundamental limitations of underlying device fabrication technologies, is becoming increasingly difficult.

Some optical sensors may be implemented with photodiodes for detection of incident light. However, photodiodes and the circuits in which photodiodes are implemented, are also known to exhibit limitations in their light-sensing capabilities. For example, it is known that photodiodes are subject to leakage, which may be manifested as a measureable ‘dark current’ that can affect an absolute measurement of a light-level.

Accordingly, it is known to use island photodiodes in combination with associated circuitry for accurate light sensing in ambient light sensing and proximity sensing, and capable of meeting stringent requirements relating to, among other things, sensitivity and signal-to-noise ratio.

An island photodiode 2 is shown in FIGS. 1A and 1B. FIG. 1A is a schematic cross-section of the island photodiode 2 which shows the island photodiode 2 located behind a display 4 such as an OLED display of an electronic device. The island photodiode 2 comprises a plurality of n-wells 10a, 10b implemented in a larger p-well 20, or a bulk p-substrate. FIG. 1B is a schematic plan view of the island photodiode 2 of FIG. 1A. From FIG. 1B, it can be seen that the island photodiode 2 comprises a plurality of n-wells 10a-10e, and that a total area of the n-wells 10a-10e is substantially lower than a total area of the larger p-well 20, or a bulk p-substrate. The plurality of n-wells 10a-10e are connected by an electively conductive contact (not shown), thus forming a cathode of the island photodiode 2. Similarly, an electively conductive contact (not shown) may be made to the larger p-well 20, or a bulk p-substrate, thus forming an anode of the island photodiode 2. The p-well 20 may define a light receiving area which is, in use, exposed to incident light. As shown in FIG. 1A, each n-well 10a, 10b is separated from the surrounding larger p-well 20 by an associated depletion region 15a, 15b.

In use, incident light such as light leakage 24 from the back of the OLED display 4 or ambient light 28 which travels through the OLED display 4 from a scene in front of the OLED display 4 may strike the light receiving area of the island photodiode 2 and generate electron-hole pairs 30. When an electron-hole pair 30 reaches any depletion region 15a, 15b, and/or when an electron-hole pair 30 is generated in any depletion region 15a, 15b, the electrons and holes are swept apart by the inherent electric field in the depletion region, and may produce a photocurrent in external circuitry connected to the anode and cathode of the island photodiode 2.

In contrast to known n-well photodiodes wherein an n-well may cover most or all of a light receiving area of the photodiode, in the island photodiode 2 only a relatively small portion of the light receiving area of the island photodiode 2 comprises n-wells 10a. As such, an effective area of an island photodiode relatively small, and thus a capacitance of the island photodiode is also relatively small.

FIG. 2A depicts a light-sensing circuit 50. The circuit 50 includes the island photodiode 2 and external circuitry 51 which is connected to the anode and cathode of the island photodiode 2. The circuit 50 is for high-sensitivity light sensing, and is particularly suitable for use in applications such as ambient light sensing, proximity sensing and flicker detection, where an intensity of light to be sensed may be particularly low. The external circuitry 51 includes an op-amp 54, a feedback capacitor 56, a voltage amplifier 56 and A/D converter 58.

In use, exposure of the light sensitive area of the island photodiode 2 to incident light causes the generation of carriers in the light sensitive area of the island photodiode 2 and the flow of a photocurrent around the circuit 50 which charges the feedback capacitor 56. This results in the op-amp 54 developing an output voltage which is then amplified by the voltage amplifier 56 and converted to a digital count by the A/D converter 58. A first digital count may be recorded at a start of an integration period and a second digital count may be recorded at an end of the integration period. A difference between the first and second digital counts may provide a more accurate indication of an intensity of light incident upon the light receiving area of the island photodiode 2 than a single measurement. That is, errors such as systematic errors that may be introduced due to dark current, can be accounted for. As such, extremely high-sensitivity measurements of an intensity of incident light may be made. It will be appreciated that although FIG. 2A depicts a single island photodiode 2, a plurality of island photodiodes may be used. For example, a 1D or 2D array of island photodiodes may be used, having a common cathode coupled to the op-amp 54 and the feedback capacitor 56.

FIG. 2B depicts a further light-sensing circuit 100. The circuit 100 includes the island photodiode 2 and external circuitry 101 which is connected to the anode and cathode of the island photodiode 2. The circuit 100 is for high-sensitivity light sensing, and is particularly suitable for use in applications such as ambient light sensing, proximity sensing and flicker detection, where an intensity of light to be sensed may be particularly low.

The external circuitry 101 comprises a first transistor 105. The first transistor 105 is configurable to reset a voltage-level at a circuit node 110 to a voltage-level defined by a voltage reference 120. In some embodiments, the voltage reference 120 may be a power supply rail, e.g., VDD.

A gate of the first transistor 105 is coupled to processing circuitry 115. The processing circuitry 115 may for example, comprise a processor, digital logic, a state machine, or the like. In some embodiments, the processing circuitry 115 may comprise a programmable processor and a memory.

A source of the first transistor 105 is coupled to the voltage reference 120. A drain of the first transistor 105 is coupled to the circuit node 110. The processing circuitry 115 may be configurable to control a voltage at the gate of the first transistor to enable current flow between the source and drain. As such, the processing circuitry 115 is configurable to reset a voltage-level at a circuit node 110 to a voltage-level of the voltage reference 120, minus any voltage dropped across the source-drain of the first transistor 105.

Also depicted in the example circuit of FIG. 2B is a further transistor 125 configured as a source-follower. A gate of the further transistor 125 is coupled to the circuit node 110. A drain of the further transistor 125 is coupled to the voltage reference 120, and a source of the further transistor 125 is coupled to measurement circuitry 130. As such, the further transistor 125 operates as a buffer, enabling a voltage-level corresponding to a voltage-level at the circuit node 110 to be measured by the measurement circuitry 130, without drawing significant current from the circuit node 110.

The measurement circuitry 130 comprises a voltage amplifier 135 and an analog-to-digital converter 140. In use, the voltage amplifier 135 may be configured to amplifier a voltage at the source of the further transistor 125, such as to use a greater proportion of a dynamic range of the analog-to-digital converter 140.

The voltage amplifier 135 may comprise an operational amplifier configured as a non-inverting operational amplifier.

The analog-to-digital converter 140 may be of any appropriate type as known in the art, for example a delta-sigma modulator, a successive approximation analog-to-digital converter, or the like.

As such, the measurement circuitry 130 is configured to measure the voltage-level corresponding to the voltage-level at the circuit node 110. That is, the measurement circuitry 130 is configured to measure the voltage-level at the circuit node 110 minus any voltage drop across the further transistor 125.

The processing circuitry 115 is configured to control the measurement circuitry 130 and/or receive an output from the measurement circuitry 130. That is, the processing circuitry 115 may configure the measurement circuitry to measure the voltage-level at the circuit node 110.

As shown in FIG. 2B, the cathode of the island photodiode 2 is coupled to the circuit node 110, e.g. to drain 110 of the first transistor 105 and the gate of the further transistor 125. The anode of the island photodiode 2 is coupled to a further voltage reference 185 which in the example circuit 100 of FIG. 2B, is a ground reference, e.g. 0 volts.

Operation of the circuit 100 is as follows. At an initial time, the first transistor 105 is turned on, e.g. a voltage is applied at the gate of the first transistor to enable current to flow from source to drain, thereby charging the island photodiode 2 and setting an initial voltage-level at the cathode, e.g. the circuit node 110, to a voltage-level defined by the voltage reference 120.

Subsequently, the first transistor 105 is turned off, thereby isolating the cathode of the island photodiode 2 from the voltage reference 120. A time when the first transistor 105 is turned off establishes a start of an integration period. The integration period may commence at a time after the first transistor 105 is turned off.

The processing circuitry 115 comprises a timer, or is configured to operate as a timer, to define the integration period.

As the island photodiode 2 is exposed to incident light, a generated photocurrent discharges the cathode of the island photodiode 2. As such, a voltage-level at the circuit node 110 drops. That is, the island photodiode 2 is configured to vary the voltage-level at the circuit node 110 in response to light incident upon the island photodiode 2 during the integration period.

As described above, the voltage amplifier 135 and analog to digital converter 140 are configured to measure the voltage level at the circuit node 110.

The processing circuitry 115 is configured to control the first transistor 105 to reset the voltage-level at the circuit node 110 and to subsequently configure the measurement circuitry 130 to measure the voltage-level at a start and then at an end of the integration period. That is, in order to reduce the effects of noise, the processing circuitry 115 is configured to control the measurement circuitry 130 to perform two measurements. A difference between these measurements may provide a more accurate indication of an intensity of light incident upon the light receiving area of the island photodiode 2 than a single measurement. That is, errors such as systematic errors that may be introduced due to dark current, can be accounted for. As such, extremely high-sensitivity measurements of an intensity of incident light may be made.

The processing circuitry 115 may be configured to determine the difference between the measurements. An output from the analog-to-digital converter 140 may be provided to the processing circuitry 115 for this purpose.

It will be appreciated that although FIG. 2B depicts a single island photodiode 2, a plurality of island photodiodes may be used. For example, a 1D or 2D array of island photodiodes may be used, having a common cathode coupled to the circuit node 110.

The island photodiode 2 has an extremely low capacitance, relative to a ‘traditional’ p-n junction based n-well photodiodes or pinned photodiode. As such, a rate of discharge, and hence rate at which a voltage at a cathode of the island photodiode 2 may drop from the voltage-level defined by the voltage reference 120 to a lower voltage-level, may be high. Thus, use of the island photodiode 2 may lead to an extremely sensitive ambient light detection, thus necessitating the above-described measurement of the voltage-level at the circuit node 110 at the start and end of the integration period to minimize errors, e.g., to ensure high sensitivity while maintaining a sufficiently high signal-to-noise ratio.

Due to the low capacitance of island photodiodes, use of an island photodiode 2 in the light-sensing circuit 50 of FIG. 2A or the light sensing circuit 100 of FIG. 2B may result in an extremely sensitive light-sensing circuit. That is, due to the inherent low capacitance of the island photodiode 2, only a small photocurrent incurred by a low intensity of incident light may result in a relatively large change in the voltage-level at the cathode of the photodiode. Such sensitivity, coupled with the measurements of the digital count or voltage-level at a start and at an end of the integration period may enable extremely high-sensitivity sensing of low-intensity incident light.

However, when an ambient light sensor (ALS), which includes the island photodiode 2, is used behind a display such as the OLED display 4 like that shown in FIG. 1A, it is known that light may leak from the back of the OLED display 4 onto the island photodiode 2. Consequently, it is known to only measure light using the island photodiode 2 when the OLED display is OFF by synchronizing the island photodiode 2 integration period with the period when the OLED display is OFF.

However, a problem with the use of an ALS, which includes the island photodiode 2 behind a display such as the OLED display 4 and which is configured to only measure light when the OLED 4 display is OFF is that the island photodiode 2 may only recover slowly once the OLED display is turned OFF. This may create errors in the photocurrent measurement during the integration period even when the OLED display is turned OFF during the integration period. This may be particularly problematic for low light levels. Moreover, it has been discovered that carriers generated in the p-well 20 of the island photodiode 2 between the n-wells 10a-10e as a result of light leakage from the back of the OLED display may remain trapped in defects in the p-well 20 for periods exceeding 1-2 ms. In effect, this means that even when the OLED display is turned OFF periodically for periods of 300-400 μs, the carriers generated in the p-well 20 as a result of light leakage from the back of the OLED display may contribute to the photocurrent during the integration period leading to an inaccuracy in the measurement of the ambient light level.

### SUMMARY

According to an aspect of the present disclosure there is provided an island photodiode comprising:
a semiconductor chip having one or more island photodiode regions and one or more carrier collection regions,
wherein the one or more island photodiode regions and the one or more carrier collection regions are located in a light receiving area of the semiconductor chip with the one or more of the carrier collection regions being arranged at least partially around each island photodiode region, and
wherein the one or more carrier collection regions are electrically addressable separately from the one or more island photodiode regions.

The one or more carrier collection regions may be configurable between a carrier collection state in which the one or more carrier collection regions collect carriers generated in the light receiving area and a carrier non-collecting state in which the one or more carrier collection regions do not collect carriers generated in the light receiving area. For example, the one or more carrier collection regions may be configurable between the carrier collection state and the carrier non-collecting state in response to an electrical control signal. For example, the one or more carrier collection regions may be configured to collect carriers generated in the light receiving area when a first electrical control signal value such as a first control voltage value is applied to the one or more carrier collection regions and the one or more carrier collection regions may be configured not to collect carriers generated in the light receiving area when a second electrical control signal value such as a second control voltage value is applied to the one or more carrier collection regions.

Such an island photodiode may be operated so that carriers generated in the light receiving area on exposure of the light receiving area to first light during a first time period can be collected by the one or more carrier collection regions and can flow as a current of collected carriers around a first circuit which includes the one or more carrier collection regions and first external circuitry during a first time period. The collection of the carriers generated in the light receiving area during the first time period by the one or more carrier collection regions and flow of the current of collected carriers around the first circuit can be interrupted during a second time period which is different to the first time period. The carriers generated in the light receiving area on exposure of the light receiving area to second light during the second time period can be collected by the one or more island photodiode regions and can flow as a photocurrent around a second circuit which includes the one or more island photodiode regions and second external circuitry during the second time period. The collection of the carriers during the first time period may serve to prevent or to suppress the number of carriers which were generated in the light receiving area as a result of exposure of the light receiving area to the first light during the first time period but which are collected in the island photodiode regions and which contribute to the photocurrent during the second time period, thereby improving the accuracy of the measurement of the photocurrent during the second time period and therefore also the accuracy of the measurement of the light incident on the light receiving area during the second time period. This may be particularly advantageous when the island photodiode is located behind a display and where the first time period corresponds to a period when the display is ON and the first light corresponds to light leakage from the back of the display and where the second time period corresponds to a period when the display is OFF and the second light corresponds to ambient light which travels from a scene in front of the display through the display to the light receiving area.

Optionally, each island photodiode region is surrounded by one or more of the carrier collection regions.

Optionally, the one or more carrier collection regions include a carrier collection grid region which extends across the light receiving area, wherein the carrier collection grid region defines one or more grid areas, and wherein each island photodiode region is located in a corresponding grid area.

Optionally, the one or more carrier collection regions include a carrier collection guard ring region which is arranged around the one or more island photodiode regions.

Optionally, each portion of the carrier collection grid region extends from one point on a perimeter of the carrier collection guard ring region to another point on the perimeter of the carrier collection guard ring region.

Optionally, the one or more carrier collection regions are defined by a carrier collection layer which defines one or more apertures in the carrier collection layer, wherein each island photodiode region is located in a corresponding aperture in the carrier collection layer.

Optionally, each island photodiode region comprises a corresponding doped well region of the semiconductor chip.

Optionally, each carrier collection region comprises a corresponding doped well region of the semiconductor chip.

Optionally, the one or more island photodiode regions and the one or more carrier collection regions are formed by doping different areas of the semiconductor chip with the same type of dopant and/or the same dopant material.

Optionally, the one or more island photodiode regions and the one or more carrier collection regions are formed in a larger doped well region or a doped substrate of the semiconductor chip, and wherein the larger doped well region or the doped substrate is doped with the opposite type of dopant to the dopant or dopants of the one or more island photodiode regions and the one or more carrier collection regions.

Optionally, each island photodiode region comprises an n-doped well region of the semiconductor chip.

Optionally, each carrier collection region comprises an n-doped well region of the semiconductor chip.

Optionally, the one or more island photodiode regions and the one or more carrier collection region are formed in a larger p-doped well region or a p-doped substrate of the semiconductor chip.

Optionally, the island photodiode comprises one or more electrically conductive gates, each gate being electrically isolated from a semiconductor material of the semiconductor chip by a layer of electrically insulating material. The one or more gates may overlap a “source/drain” semiconductor region of the semiconductor chip which is doped with the opposite dopant type to the island photodiode regions. Application of a suitable voltage to one or more of the gates creates one or more of the corresponding carrier collection regions in the semiconductor material of the semiconductor chip in one or more regions of the semiconductor chip underlying the one or more gates.

Optionally, each electrically conductive gate comprises, or is formed from, polysilicon.

Optionally, the voltage is selected to create a neutral region or an accumulated region in the one or more corresponding carrier collection regions in the semiconductor material of the semiconductor chip in the one or more regions of the semiconductor chip underlying the one or more gates. When a neutral region or an accumulated region is created in the one or more corresponding carrier collection regions under the gate, the one or more corresponding carrier collection regions are in a non-collecting state.

Optionally, the voltage is selected to create an inverted region or depletion region in the one or more corresponding carrier collection regions in the semiconductor material of the semiconductor chip in the one or more regions of the semiconductor chip underlying the one or more gates. When an inverted region or a depletion region is created in the one or more corresponding carrier collection regions under the gate, the one or more corresponding carrier collection regions are in a carrier collecting state.

Optionally, the one or more electrically conductive gates include a gate grid which extends across the light receiving area, wherein the gate grid defines one or more grid areas, and wherein each island photodiode region is located in a corresponding grid area.

Optionally, the one or more carrier collection regions include a carrier collection guard ring region which is arranged around the one or more island photodiode regions.

Optionally, the carrier collection guard ring region is formed in a larger doped well region or a doped substrate of the semiconductor chip, wherein the larger doped well region or the doped substrate is doped with the opposite type of dopant to the dopant or dopants of the carrier collection guard ring region.

Optionally, each portion of the gate grid extends from a position overlying one point on a perimeter of the carrier collection guard ring region to a position overlying another point on the perimeter of the carrier collection guard ring region.

Optionally, one or more portions of the gate grid extend to a position overlying one or more of the island photodiode regions.

Optionally, the carrier collection guard ring region comprises a corresponding doped well region of the semiconductor chip.

Optionally, the carrier collection guard ring region is formed in a larger doped well region or a doped substrate of the semiconductor chip, and wherein the larger doped well region or the doped substrate is doped with the opposite type of dopant of the carrier collection guard ring region.

Optionally, the island photodiode comprises an island photodiode electrode and a carrier collection electrode, wherein the carrier collection electrode is configured to form an electrically conductive connection between the one or more carrier collection regions and the first external circuitry, and wherein the island photodiode electrode is configured to form an electrically conductive connection between the one or more island photodiode regions and the second external circuitry.

According to an aspect of the present disclosure there is provided an electronic device comprising an island photodiode as described above and a display, wherein the island photodiode is located behind the display and the island photodiode is configured to receive light through the display from a scene located in front of the display.

Optionally, the display comprises an OLED display.

According to an aspect of the present disclosure there is provided a method of operating an island photodiode as described above, the method comprising:
exposing the light receiving area to first light during a first time period so as to generate carriers in the light receiving area, and collecting, in the one or more carrier collection regions, at least some of the carriers generated in the light receiving area during the first time period so as to cause the collected carriers to flow around a first circuit which includes the one or more carrier collection regions and first external circuitry during the first time period;
interrupting the collection of carriers in the one or more carrier collection regions and exposing the light receiving area to second light during a second time period so as to generate carriers in the light receiving area;
collecting, in the one or more island photodiode regions, at least some of the carriers generated in the light receiving area during the second time period so as to cause a photocurrent to flow around a second circuit which includes the one or more island photodiode regions and second external circuitry during the second time period; and
using the second external circuitry to determine an intensity of the second light incident on the light receiving area during a measurement time period based on a measurement of a quantity representative of the photocurrent flowing around the second circuit through the one or more island photodiode regions during the measurement time period, wherein the measurement time period occurs during the second time period or the measurement time period coincides with the second time period.

Such a method of operating an island photodiode may serve to prevent or to suppress the number of carriers which accumulate in the light receiving area as a result of exposure of the light receiving area to the first light during the first time period but which are collected in the island photodiode regions and which contribute to the photocurrent during the second time period, thereby improving the accuracy of the measurement of the photocurrent during the second time period and therefore also the accuracy of the measurement of the light incident on the light receiving area during the second time period. This may be particularly advantageous when the island photodiode is located behind a display and where the first time period corresponds to a period when the sensor is not-active (i.e. when the sensor is not measuring the photocurrent) and may be subject to light leakage from the back of the display when the display is ON and where the second time period corresponds to a period when the sensor is active and sensing (or measuring) the photocurrent and the display is generally OFF so that the second light corresponds to ambient light which travels from a scene in front of the display through the display to the light receiving area.

Optionally, the first light comprises light leakage, for example light leakage from the back side of a display such as an OLED display.

Optionally, the second light comprises ambient light such as light from a scene located in front of the display.

Optionally, the measurement time period occurs during the second time period and wherein a start time of the measurement time period is delayed by a predetermined delay from a start time of the second time period.

Optionally, determining an intensity of the second light incident on the light receiving area during a measurement time period based on a measurement of a quantity representative of the photocurrent flowing around the second circuit during the measurement time period comprises determining the integrated intensity of the second light incident on the light receiving area during a measurement time period.

It should be understood that any one or more of the features of any one of the foregoing aspects of the present disclosure may be combined with any one or more of the features of any of the other foregoing aspects of the present disclosure.

### BRIEF DESCRIPTION OF THE DRAWINGS

An island photodiode and associated method of operation will now be described by way of non-limiting example only with reference to the accompanying drawings of which:

FIG. 1A is a schematic cross-section of a known island photodiode located behind an OLED display;

FIG. 1B is a schematic plan view of the known island photodiode shown in FIG. 1A;

FIG. 2A illustrates a known light-sensing circuit including an island photodiode;

FIG. 2B illustrates a further known light-sensing circuit including an island photodiode;

FIG. 3A is a schematic plan view of a first island photodiode according to the present disclosure;

FIG. 3B is a timing diagram illustrating control voltages as a function of time during the operation of the first island photodiode of FIG. 3A;

FIG. 4 is a schematic plan view of a second island photodiode according to the present disclosure;

FIG. 5A is a schematic plan view of a third island photodiode according to the present disclosure;

FIG. 5B is a timing diagram illustrating control voltages as a function of time during the operation of the third island photodiode of FIG. 5A;

FIG. 6 is a schematic plan view of a fourth island photodiode according to the present disclosure; and

FIG. 7 is a schematic plan view of a fifth island photodiode according to the present disclosure.

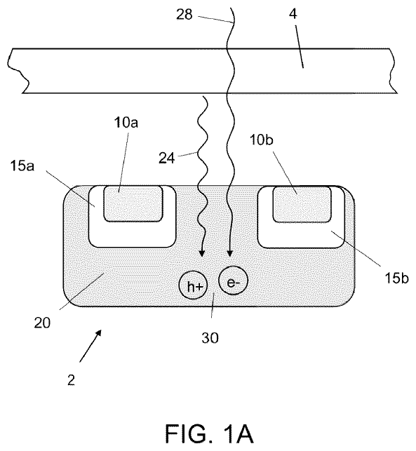

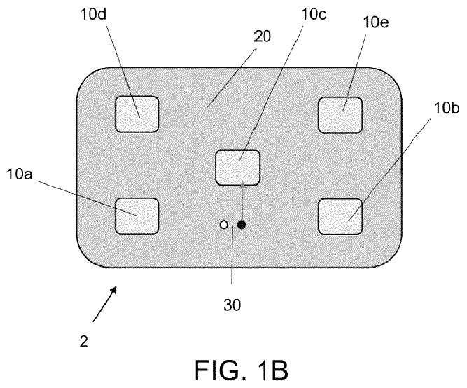

### DETAILED DESCRIPTION OF THE DRAWINGS

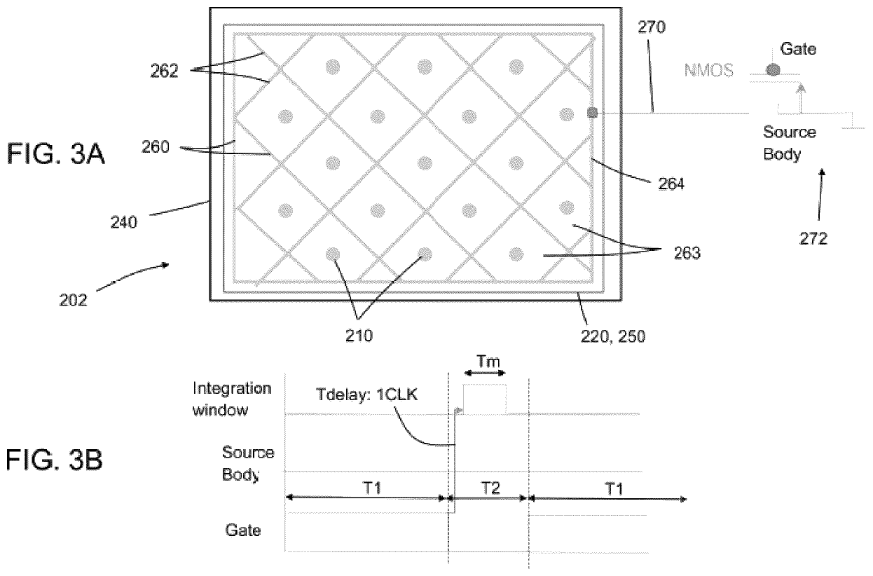

Referring to FIG. 3A there is shown a first island photodiode designated 202. Although not shown in FIG. 3A, it should be understood that, in use, the island photodiode 202 may be located behind a display such as an OLED display of an electronic device.

The island photodiode 202 comprises a semiconductor chip 240 having a plurality of island photodiode regions 210 and a plurality of carrier collection regions generally designated 260. The island photodiode regions 210 and the carrier collection regions 260 are located in a light receiving area 250 of the semiconductor chip 240 with the carrier collection regions 260 being arranged so as to surround each island photodiode region 210. As will be described in more detail below, the carrier collection regions 260 are electrically addressable separately from the island photodiode regions 210.

Each island photodiode region 210 comprises a corresponding n-doped well region of the semiconductor chip 240 formed in a larger p-doped well region 220 or a p-doped substrate of the semiconductor chip 240.

The carrier collection regions 260 include a carrier collection grid region 262 and a carrier collection guard ring region 264. Each of the carrier collection grid region 262 and the carrier collection guard ring region 264 comprises a corresponding n-doped well region of the semiconductor chip 240 formed in the larger p-doped well region 220 or the p-doped substrate of the semiconductor chip 240.

The carrier collection grid region 262 extends across the light receiving area 250, wherein the carrier collection grid region 262 defines one or more grid areas 263, and wherein each island photodiode region 210 is located in a corresponding grid area 263. The carrier collection guard ring region 264 is arranged around the plurality of island photodiode regions 210. Each portion of the carrier collection grid region 262 extends from one point on a perimeter of the carrier collection guard ring region 264 to another point on the perimeter of the carrier collection guard ring region 264.

The first island photodiode 202 comprises a carrier collection electrode 270 which is configured to form an electrically conductive connection between the carrier collection regions 260 and corresponding first external circuitry 272 in the form of an NMOS switch connected to a lower reference voltage such as a 0V or a ground reference voltage.

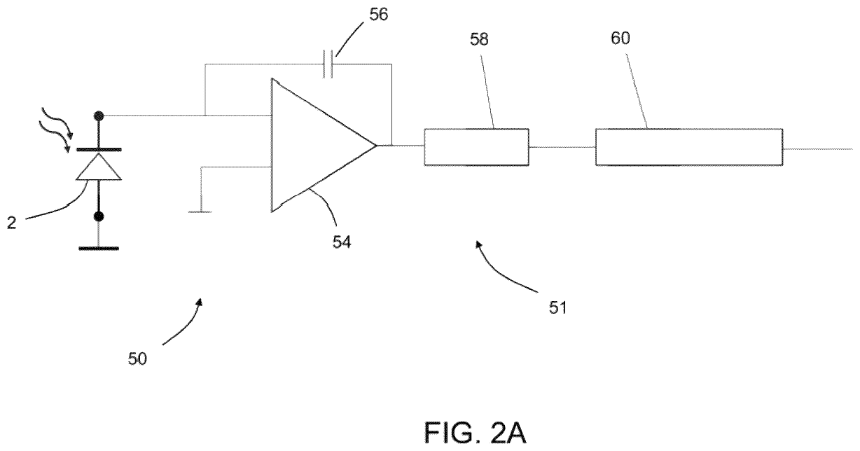

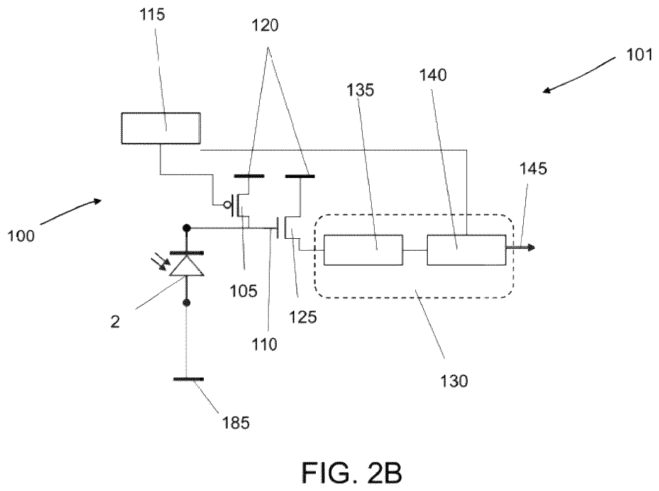

Although not shown in FIG. 3A, it should be understood that the island photodiode 202 further comprises island photodiode electrodes, wherein the island photodiode electrodes are configured to form an electrically conductive connection between the island photodiode regions 210 and corresponding second external circuitry like the circuitry 51 described with reference to FIG. 2A or the circuitry 101 described with reference to FIG. 2B for measuring a quantity representative of the photocurrent flowing around a circuit through the island photodiode regions 210 and the second external circuitry during a measurement time period. For example, the island photodiode 202 may further comprise an anode and a cathode which is common to the island photodiode regions 210, wherein the anode and cathode are configured to form an electrically conductive connection between the island photodiode regions 210 and the second external circuitry.

As a consequence of the above-mentioned electrical connections, one of ordinary skill in the art will understand that the carrier collection regions 260 are electrically addressable separately from the island photodiode regions 210.

As a consequence of the above-mentioned electrical connections the one or more carrier collection regions 260 are configurable between a carrier collection state in which the one or more carrier collection regions 260 collect carriers generated in the light receiving area 250 and a carrier non-collecting state in which the one or more carrier collection regions 260 do not collect carriers generated in the light receiving area 250. For example, the one or more carrier collection regions 260 are configured to collect carriers generated in the light receiving area 250 when a first electrical control signal value such as a first control voltage value is applied to the one or more carrier collection regions 260 and the one or more carrier collection regions 260 are configured not to collect carriers generated in the light receiving area 250 when a second electrical control signal value such as a second control voltage value is applied to the one or more carrier collection regions 260.

### Consequently:

carriers generated in the light receiving area 250 on exposure of the light receiving area 250 to first light during a first time period can be collected by the carrier collection regions 260 and can flow as a current of collected carriers around the first circuit which includes the carrier collection regions 260 and the first external circuitry 272 during a first time period;
collection, by the carrier collection regions 260, of the carriers generated in the light receiving area 250 during the first time period and flow of the current of collected carriers around the first circuit can be interrupted during a second time period which is different to the first time period; and
carriers generated in the light receiving area 250 on exposure of the light receiving area 250 to second light during the second time period can be collected by the island photodiode regions 210 and can flow as a photocurrent around the second circuit which includes the island photodiode regions 210 and the second external circuitry during the second time period.

In use, the island photodiode 202 may be operated according to a method which comprises exposing the light receiving area 250 to first light during a first time period T1 shown in FIG. 3B so as to generate carriers in the light receiving area 250, and collecting, in the carrier collection regions 260, at least some of the carriers generated in the light receiving area 250 during the first time period so as to cause the collected carriers to flow around the first circuit which includes the carrier collection regions 260 and the first external circuitry 272 during the first time period T1. For example, the carriers may be generated in the light receiving area 250 in one of the grid areas 263 and may travel to the carrier collection grid region 262 or to the carrier collection guard ring region 264 as a result of diffusion through the semiconductor material of the semiconductor chip 240 during the first time period T1.

As shown in FIG. 3B, the voltage on the gate of the NMOS switch of the first external circuitry 272 is set high during the first time period T1 to ensure that the carrier collection grid region 262 and the carrier collection guard ring region 264 are tied to the lower reference voltage during the first time period T1. In effect, this creates a depletion region between the n-doped well of the carrier collection grid region 262 and the larger p-type well or p-type substrate 220 and a depletion region between the n-doped well of the carrier collection guard ring region 264 and the larger p-type well or p-type substrate 220. Consequently, upon reaching the carrier collection grid region 262 or the carrier collection guard ring region 264, the generated carriers are collected in the carrier collection regions 260 and swept apart by the electric fields in the carrier collection regions 260, whereupon the collected carriers flow around the first circuit which includes the carrier collection regions 260 and the first external circuitry 272 during the first time period T1. Moreover, the gate signal may be synchronized to activate when the sensor is not measuring, and with the display of the electronic device such that the first light may be back light which leaks from the display of the electronic device during the first time period T1 when the display is activated.

The method comprises interrupting the collection of carriers in the carrier collection regions 260 and exposing the light receiving area to second light during a second time period T2, when the sensor is measuring the incident light, so as to generate carriers in the light receiving area by setting the voltage on the gate of the NMOS switch of the first external circuitry 272 to zero during the second time period T2 as shown in FIG. 3B.

The method comprises collecting, in the one or more island photodiode regions 210, at least some of the carriers generated in the light receiving area 250 during the second time period T2 so as to cause a photocurrent to flow around the second circuit which includes the island photodiode regions 210 and the second external circuitry during the second time period T2. This may be accomplished by synchronizing a signal applied to the gate of the NMOS switch of the first external circuitry 272 with the display of the electronic device such that the display is deactivated during the second time period T2 and the second light is ambient light which is incident on the light receiving area 250 through the display of the electronic device during the second time period T2.

The method further comprises using the second external circuitry to determine an intensity of the second light incident on the light receiving area 250 during a measurement time period Tm based on a measurement of a quantity representative of the photocurrent flowing around the second circuit through the one or more island photodiode regions 210 during the measurement time period Tm, wherein the measurement time period Tm occurs during the second time period T2. Specifically, as shown in FIG. 3B, the start of the measurement time period Tm may be delayed relative to the start of the second time period T2 by a delay which may, in some embodiments, be of the order of 3 μs.

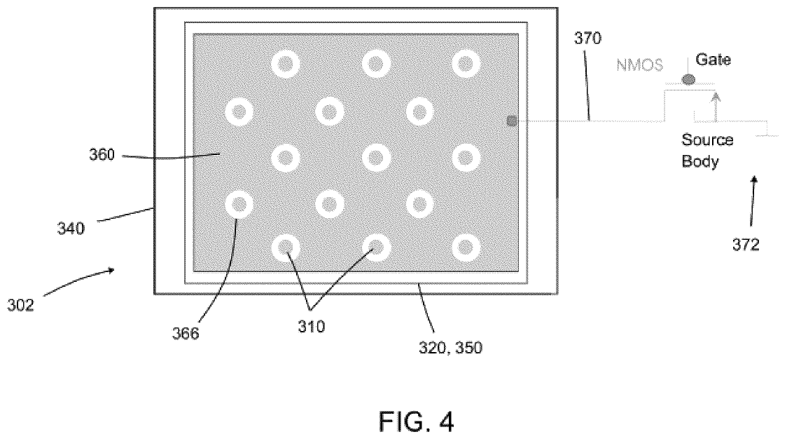

Referring now to FIG. 4 there is shown a second island photodiode designated 302 comprising a semiconductor chip 340 having a plurality of island photodiode regions 310 and a carrier collection region generally designated 360. The island photodiode regions 310 and the carrier collection region 360 are located in a light receiving area 350 of the semiconductor chip 340. The carrier collection region 360 is defined by a carrier collection layer which defines one or more apertures 366 in the carrier collection layer, wherein each island photodiode region 310 is located in a corresponding aperture 366 in the carrier collection layer such that the carrier collection region 360 surrounds each island photodiode region 310. Like the first island photodiode 202 of FIG. 3A, the carrier collection region 360 is electrically addressable separately from the island photodiode regions 310.

Like the first island photodiode 202 of FIG. 3A, each island photodiode region 310 of the second island photodiode 302 comprises a corresponding n-doped well region of the semiconductor chip 340 formed in a larger p-doped well region 320 or a p-doped substrate of the semiconductor chip 340. Similarly, the carrier collection region 360 comprises a corresponding n-doped well region of the semiconductor chip 340 formed in the larger p-doped well region 320 or the p-doped substrate of the semiconductor chip 340.

The island photodiode 302 comprises a carrier collection electrode 370 which is configured to form an electrically conductive connection between the carrier collection region 360 and corresponding first external circuitry 372 in the form of an NMOS switch connected to a lower reference voltage such as a 0V or a ground reference voltage.

The operation of the second island photodiode 302 is identical to the operation of the first island photodiode 202 described above with reference to FIGS. 3A and 3B.

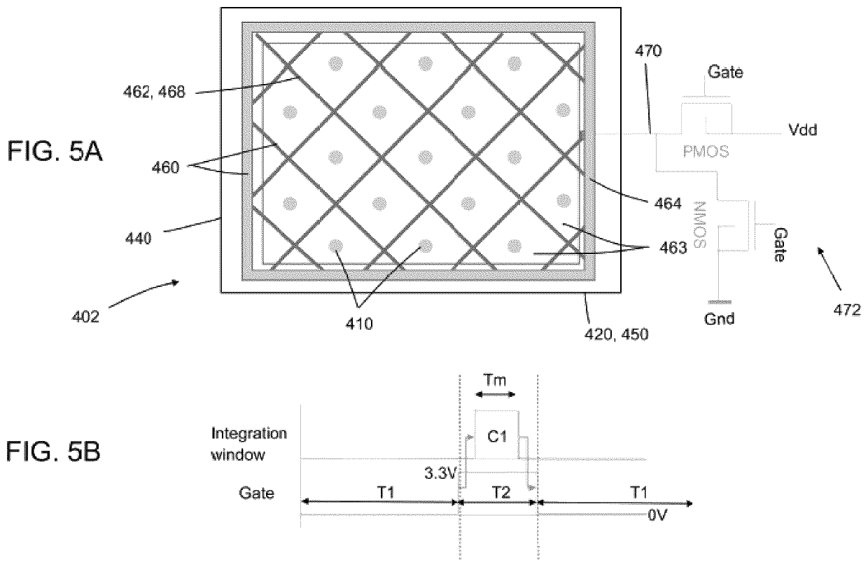

Referring now to FIG. 5A there is shown a third island photodiode designated 402 comprising a semiconductor chip 440 having a plurality of island photodiode regions 410 and a plurality of carrier collection regions generally designated 460. The island photodiode regions 410 and the carrier collection regions 460 are located in a light receiving area 450 of the semiconductor chip 440 with the carrier collection regions 460 being arranged so as to surround each island photodiode region 410.

As will be described in more detail below, the carrier collection regions 460 are electrically addressable separately from the island photodiode regions 410.

Like the first island photodiode 202 of FIG. 3A, each island photodiode region 410 of the third island photodiode 402 comprises a corresponding n-doped well region of the semiconductor chip 440 formed in a larger p-doped well region 420 or a p-doped substrate of the semiconductor chip 440.

Like the first island photodiode 202 of FIG. 3A, the carrier collection regions 460 of the third island photodiode 402 include a carrier collection guard ring region 464 which extends around the island photodiode regions 410. Like the first island photodiode 202 of FIG. 3A, the carrier collection guard ring region 464 of the third island photodiode 402 comprises a corresponding n-doped well region of the semiconductor chip 440 formed in the larger p-doped well region 420 or the p-doped substrate of the semiconductor chip 440.

However, unlike the first island photodiode 202 of FIG. 3A, the third island photodiode 402 of FIG. 5A comprises an electrically conductive gate grid 468 which is electrically isolated from a semiconductor material of the semiconductor chip 440 by a layer of electrically insulating material. The electrically conductive gate grid 468 generally overlies the larger p-doped well region 420. However, at least one portion of the electrically conductive gate grid 468 overlies a semiconductor region of the opposite doping to the larger p-doped well region 420. For example, as shown in FIG. 5A, portions of the electrically conductive gate grid 468 overlie the n-doped carrier collection guard ring region 464. Application of a suitable voltage to the electrically conductive gate grid 468 induces a carrier collection grid region 462 in the form of an inverted or depleted grid region in the larger p-doped well region 420 of the semiconductor material of the semiconductor chip 440 underlying the electrically conductive gate grid 468. The electrically conductive gate grid 468 comprises, or may be formed from, polysilicon. As shown in FIG. 5A, the electrically conductive gate grid 468 extends across the light receiving area 450 and defines one or more grid areas 463, wherein each island photodiode region 410 is located in a corresponding grid area 463. Each portion of the electrically conductive gate grid 468 extends from a position overlying one point on a perimeter of the carrier collection guard ring region 464 to a position overlying another point on the perimeter of the carrier collection guard ring region 464.

The island photodiode 402 comprises an electrode 470 which is configured to form an electrically conductive connection between the electrically conductive gate region 460 and corresponding first external circuitry 472 in the form of a CMOS (NMOS+PMOS) switch connected to an upper reference voltage Vdd through the PMOS and lower reference voltage of 0V, or “Gnd” through the NMOS. One of ordinary skill in the art will understand that this circuit is an example and may be accomplished in different ways to effectively switch the gate electrode 470 between Vdd and 0V.

Although not shown in FIG. 5A, it should be understood that the island photodiode 402 further comprises island photodiode electrodes, wherein the island photodiode electrodes are configured to form an electrically conductive connection between the island photodiode regions 410 and corresponding second external circuitry like the external circuitry 51 of FIG. 2A or the external circuitry 101 of FIG. 2B for measuring a quantity representative of the photocurrent flowing around a circuit through the island photodiode regions 410 and the second external circuitry during a measurement time period Tm.

As a consequence of the above-mentioned electrical connections, one of ordinary skill in the art will understand that the carrier collection regions 460 are electrically addressable separately from the island photodiode regions 410.

In use, the island photodiode 402 may be operated according to a method which comprises exposing the light receiving area 450 to first light during a first time period T1 shown in FIG. 5B so as to generate carriers in the light receiving area 450, and collecting, in the carrier collection regions 460, at least some of the carriers generated in the light receiving area 450 during the first time period so as to cause the collected carriers to flow around the first circuit which includes the carrier collection regions 460 and the first external circuitry 472 during the first time period T1. For example, the carriers may be generated in the light receiving area 450 in one of the grid areas 463 and may travel to the carrier collection grid region 462 or to the carrier collection guard ring region 464 as a result of diffusion through the semiconductor material of the semiconductor chip 440 during the first time period T1.

As shown in FIG. 5B, the voltage on the gate of the PMOS switch of the first external circuitry 472 is set high during the first time period T1 to ensure that the carrier collection grid region 462 and the carrier collection guard ring region 464 are tied to the reference voltage Vdd during the first time period T1. In effect, this creates a depleted or inverted carrier collection grid region 462 in the areas of the larger p-type well or p-type substrate 420 under the electrically conductive gate grid 468 and a depletion region between the n-doped well of the carrier collection guard ring region 464 and the larger p-type well or p-type substrate 420. Upon reaching the depletion carrier collection grid region 462, the carriers diffuse along the surface in the depletion carrier collection grid region 462 until they reach the carrier collection guard ring region 464. Upon reaching the carrier collection guard ring region 464, the generated carriers are collected in the carrier collection guard ring region 464, whereupon the collected carriers flow around the first circuit which includes the carrier collection guard ring region 464 and the first external circuitry 472 during the first time period T1. The time T1 is usually when the sensor is not measuring and reporting the light incident on it and T2 is the time when the sensor is measuring the light incident upon it. Moreover, the gate signal may be synchronized with the display of the electronic device such that the first light may be back light which leaks from the display of the electronic device during the first time period T1 when the display is activated.

The method comprises interrupting the collection of carriers in the carrier collection regions 460 and exposing the light receiving area to second light during a second time period T2 so as to generate carriers in the light receiving area by setting the voltage on the gate of the PMOS switch of the first external circuitry 472 to 0 or a voltage that essentially is below the flat band voltage of the gate during the second time period T2 as shown in FIG. 5B. A consequence of applying this voltage to the gate of the PMOS switch, a neutral region or an accumulated region is created in the one or more corresponding carrier collection regions under the electrically conductive gate grid 468, so that the one or more corresponding carrier collection regions under the electrically conductive gate grid 468 are in a non-collecting state during the second time period T2.

The method comprises collecting, in the one or more island photodiode regions 410, at least some of the carriers generated in the light receiving area 450 during the second time period T2 so as to cause a photocurrent to flow around the second circuit which includes the island photodiode regions 410 and the second external circuitry during the second time period T2. This may be accomplished by synchronizing the signal applied to the gate of the PMOS switch with the display of the electronic device such that the display is deactivated during the second time period T2 and the second light is ambient light which is incident on the light receiving area 450 through the display of the electronic device during the second time period T2.

The method further comprises using the second external circuitry to determine an intensity of the second light incident on the light receiving area 450 during a measurement time period Tm based on a measurement of a quantity representative of the photocurrent flowing around the second circuit through the one or more island photodiode regions 410 during the measurement time period Tm, wherein the measurement time period Tm occurs during the second time period T2. Specifically, as shown in FIG. 5B, the start of the measurement time period Tm may be delayed relative to the start of the second time period T2 by a delay which may, in some embodiments, be of the order of 3 μs.

In other respects, the operation of the third island photodiode 402 is identical to the operation of the first island photodiode 202 described above with reference to FIGS. 3A and 3B.

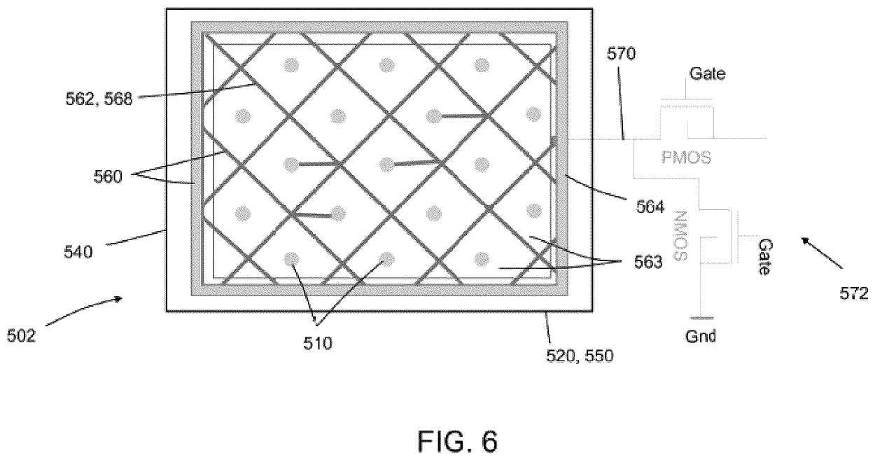

Referring now to FIG. 6 there is shown a fourth island photodiode designated 502 comprising a semiconductor chip 540 having a plurality of island photodiode regions 510 and a plurality of carrier collection regions generally designated 560. The island photodiode regions 510 and the carrier collection regions 560 are located in a light receiving area 550 of the semiconductor chip 540 with the carrier collection regions 560 being arranged so as to surround each island photodiode region 510.

As will be described in more detail below, the carrier collection regions 560 are electrically addressable separately from the island photodiode regions 510.

Like the third island photodiode 402 of FIG. 5A, each island photodiode region 510 of the fourth island photodiode 502 comprises a corresponding n-doped well region of the semiconductor chip 540 formed in a larger p-doped well region 520 or a p-doped substrate of the semiconductor chip 540.

Like the third island photodiode 402 of FIG. 5A, the carrier collection regions 560 of the fourth island photodiode 502 include a carrier collection guard ring region 564 which extends around the island photodiode regions 510. Like the third island photodiode 402 of FIG. 5A, the carrier collection guard ring region 564 of the fourth island photodiode 502 comprises a corresponding n-doped well region of the semiconductor chip 540 formed in the larger p-doped well region 520 or the p-doped substrate of the semiconductor chip 540.

Like the third island photodiode 402 of FIG. 5A, the fourth island photodiode 502 of FIG. 6 also comprises an electrically conductive gate grid 568 which is electrically isolated from a semiconductor material of the semiconductor chip 540 by a layer of electrically insulating material, wherein application of a suitable voltage to the electrically conductive gate grid 568 creates a carrier collection grid region 562 in the semiconductor material of the semiconductor chip 540 in a grid region of the semiconductor chip 540 underlying the electrically conductive gate grid 568. The electrically conductive gate grid 568 comprises, or may be formed from, polysilicon. As shown in FIG. 6, the electrically conductive gate grid 568 extends across the light receiving area 550 and defines one or more grid areas 563, wherein each island photodiode region 510 is located in a corresponding grid area 563. Each portion of the electrically conductive gate grid 568 extends from a position overlying one point on a perimeter of the carrier collection guard ring region 564 to a position overlying another point on the perimeter of the carrier collection guard ring region 564.

The island photodiode 502 comprises a carrier collection electrode 570 which is configured to form an electrically conductive connection between the carrier collection region 560 and corresponding first external circuitry 572 in the form of a CMOS (NMOS+PMOS) switch connected to an upper reference voltage Vdd through the PMOS and lower reference voltage of 0V, or “Gnd” through the NMOS. One of ordinary skill in the art will understand that this circuit is an example and may be accomplished in different ways to effectively switch the gate electrode 470 between Vdd and 0V.

However, unlike the third island photodiode 402 of FIG. 5A, in the fourth island photodiode 502, the electrically conductive gate grid 568 also extends to one or more positions overlying one or more corresponding island photodiode regions 510. In effect, this means that the inverted or depleted regions that may be created under the electrically conductive gate grid 568 extend to the island photodiode regions 510. This may help to improve the removal of generated carriers from the inverted or depleted regions created under the electrically conductive gate grid 568 when a voltage on the gate of the PMOS switch of the first external circuitry 572 is set low during a first time period T1 because the generated carriers may not only be swept apart in the depletion region in the carrier collection guard ring region 564 to form a collected carrier current which flows around a first circuit which includes the carrier collection guard ring region 564 and the first external circuitry 572 during the first time period T1, but the generated carriers may also be swept apart in the depletion regions in the island photodiode regions 510 to form a collected carrier current which flows around a second circuit which includes the island photodiode regions 510 and second external circuitry such as the external circuitry 51 of FIG. 2A or the external circuitry 101 of FIG. 2B.

In all other respects the fourth island photodiode 502 of FIG. 6 is identical to the third island photodiode 402 of FIG. 5A.

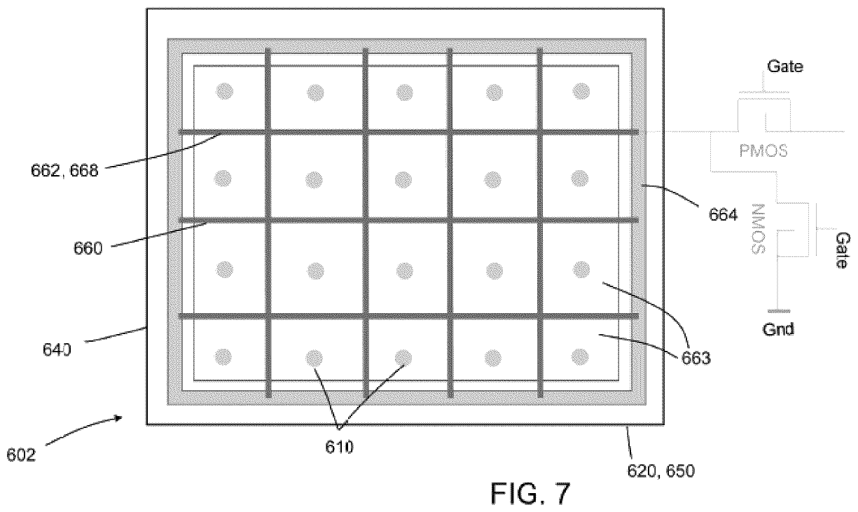

Referring now to FIG. 7 there is shown a fifth island photodiode designated 602 comprising a semiconductor chip 640 having a plurality of island photodiode regions 610 and a plurality of carrier collection regions generally designated 660. The island photodiode regions 610 and the carrier collection regions 660 are located in a light receiving area 650 of the semiconductor chip 640 with the carrier collection regions 660 being arranged so as to surround each island photodiode region 610.

Like the third island photodiode 402 of FIG. 5A, each island photodiode region 610 of the fifth island photodiode 602 comprises a corresponding n-doped well region of the semiconductor chip 640 formed in a larger p-doped well region 620 or a p-doped substrate of the semiconductor chip 640.

Like the third island photodiode 402 of FIG. 5A, the carrier collection regions 660 of the fifth island photodiode 602 include a carrier collection guard ring region 664 which extends around the island photodiode regions 610. Like the third island photodiode 402 of FIG. 5A, the carrier collection guard ring region 664 of the fifth island photodiode 602 comprises a corresponding n-doped well region of the semiconductor chip 640 formed in the larger p-doped well region 620 or the p-doped substrate of the semiconductor chip 640.

Like the third island photodiode 402 of FIG. 5A, the fifth island photodiode 602 of FIG. 7 also comprises an electrically conductive gate grid 668 which is electrically isolated from a semiconductor material of the semiconductor chip 640 by a layer of electrically insulating material and at least some part of it overlies the carrier collection guard ring region 664, wherein application of a suitable voltage to the electrically conductive gate grid 668 creates a carrier collection grid region 662 in the semiconductor material of the semiconductor chip 640 in a grid region of the semiconductor chip 640 underlying the electrically conductive gate grid 668. The electrically conductive gate grid 668 comprises, or may be formed from, polysilicon. As shown in FIG. 7, the electrically conductive gate grid 668 extends across the light receiving area 650 and defines one or more grid areas 663, wherein each island photodiode region 610 is located in a corresponding grid area 663. Each portion of the electrically conductive gate grid 668 extends from a position overlying one point on a perimeter of the carrier collection guard ring region 664 to a position overlying another point on the perimeter of the carrier collection guard ring region 664.

The fifth island photodiode designated 602 is identical to the third island photodiode 402 of FIG. 5A in all respects except that the electrically conductive gate grid 668 of the fifth island photodiode designated 602 of FIG. 7 is oriented differently to the electrically conductive gate grid 468 of the third island photodiode 402 of FIG. 5A. Specifically, the electrically conductive gate grid 668 of the fifth island photodiode designated 602 of FIG. 7 is oriented so that different portions of the electrically conductive gate grid 668 run parallel to different sides of the carrier collection guard ring region 664.

Although preferred embodiments of the disclosure have been described in terms as set forth above, it should be understood that these embodiments are illustrative only and that the claims are not limited to those embodiments. Those skilled in the art will understand that various modifications may be made to the described embodiments without departing from the scope of the appended claims. For example, the measurement time period Tm may coincide with the second time period. Although each of the island photodiode embodiments described above include a plurality of island photodiode regions, in other island photodiode embodiments there may only be one island photodiode region. Although the each of the island photodiode embodiments described above include one or more island photodiode regions, wherein each island photodiode region comprises an n-doped well region of a semiconductor chip formed in a larger p-doped well region of the semiconductor chip or a p-doped substrate of the semiconductor chip, the one or more island photodiode regions may have the opposite polarity. That is to say that each island photodiode region may comprise a p-doped well region of a semiconductor chip formed in a larger n-doped well region of the semiconductor chip or an n-doped substrate of the semiconductor chip.

Similarly, rather than each of the one or more carrier collection regions comprising an n-doped well region of a semiconductor chip formed in a larger p-doped well region of the semiconductor chip or a p-doped substrate of the semiconductor chip, the one or more carrier collection regions may have the opposite polarity. That is to say that each carrier collection region may comprise a p-doped well region of a semiconductor chip formed in a larger n-doped well region of the semiconductor chip or an n-doped substrate of the semiconductor chip.

Each feature disclosed or illustrated in the present specification may be incorporated in any embodiment, either alone, or in any appropriate combination with any other feature disclosed or illustrated herein. In particular, one of ordinary skill in the art will understand that one or more of the features of the embodiments of the present disclosure described above with reference to the drawings may produce effects or provide advantages when used in isolation from one or more of the other features of the embodiments of the present disclosure and that different combinations of the features are possible other than the specific combinations of the features of the embodiments of the present disclosure described above.

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

Use of the term “comprising” when used in relation to a feature of an embodiment of the present disclosure does not exclude other features or steps. Use of the term “a” or “an” when used in relation to a feature of an embodiment of the present disclosure does not exclude the possibility that the embodiment may include a plurality of such features.

The use of reference signs in the claims should not be construed as limiting the scope of the claims.

### LIST OF REFERENCE NUMERALS

2 island photodiode
4 OLED display
10a-10e n-doped well island photodiode regions
15a, 15b depletion region
20 p-doped well region
24 light leakage
28 ambient light
30 electron-hole pair
100 circuit
101 external circuitry
105 first transistor
110 circuit node
115 processing circuitry
120 voltage reference
125 further transistor
130 measurement circuitry
135 voltage amplifier
140 analog-to-digital converter
145 output
150 photodiode
185 further voltage reference
202 island photodiode
210 n-doped island photodiode regions
220 p-doped well region
240 semiconductor chip
250 light receiving area
260 carrier collection region
262 carrier collection grid region
263 grid area
264 carrier collection guard ring region
270 carrier collection electrode
272 first external circuitry
302 island photodiode
310 n-doped island photodiode regions
320 p-doped well region
340 semiconductor chip
350 light receiving area
360 carrier collection region
366 aperture in carrier collection layer
370 carrier collection electrode
372 first external circuitry
402 island photodiode
410 n-doped island photodiode regions
420 p-doped well region
440 semiconductor chip
450 light receiving area
460 carrier collection region
462 carrier collection grid region
463 grid area
464 carrier collection guard ring region
468 electrically conductive gate grid
470 carrier collection electrode
472 first external circuitry
502 island photodiode
510 n-doped island photodiode regions
520 p-doped well region
540 semiconductor chip
550 light receiving area
560 carrier collection region
562 carrier collection grid region
563 grid area
564 carrier collection guard ring region
568 electrically conductive gate grid
570 carrier collection electrode
572 first external circuitry
602 island photodiode
610 n-doped island photodiode regions
620 p-doped well region
640 semiconductor chip
650 light receiving area
660 carrier collection region
662 carrier collection grid region
663 grid area
664 carrier collection guard ring region
668 electrically conductive gate grid

The invention claimed is:

1. An island photodiode comprising:
a semiconductor chip having one or more island photodiode regions and one or more carrier collection regions,
wherein the one or more island photodiode regions and the one or more carrier collection regions are located in a light receiving area of the semiconductor chip with the one or more of the carrier collection regions being arranged at least partially around each island photodiode region, and
wherein the one or more carrier collection regions are electrically addressable separately from the one or more island photodiode regions.

2. The island photodiode as claimed in claim 1, wherein the one or more carrier collection regions are configurable between a carrier collection state in which the one or more carrier collection regions collect carriers generated in the light receiving area and a carrier non-collecting state in which the one or more carrier collection regions do not collect carriers generated in the light receiving area.

3. The island photodiode as claimed in claim 1, wherein each island photodiode region is surrounded by one or more of the carrier collection regions.

4. The island photodiode as claimed in claim 1, wherein the one or more carrier collection regions include a carrier collection grid region which extends across the light receiving area, wherein the carrier collection grid region defines one or more grid areas, and wherein each island photodiode region is located in a corresponding grid area.

5. The island photodiode as claimed in claim 4, wherein the one or more carrier collection regions include a carrier collection guard ring region which is arranged around the one or more island photodiode regions.

6. The island photodiode as claimed in claim 5, wherein each portion of the carrier collection grid region extends from one point on a perimeter of the carrier collection guard ring region to another point on the perimeter of the carrier collection guard ring region.

7. The island photodiode as claimed in claim 1, wherein the one or more carrier collection regions are defined by a carrier collection layer which defines one or more apertures in the carrier collection layer, wherein each island photodiode region is located in a corresponding aperture in the carrier collection layer.

8. The island photodiode as claimed in claim 1, wherein each island photodiode region comprises a corresponding doped well region of the semiconductor chip formed in a larger doped well region or a doped substrate of the semiconductor chip, wherein the larger doped well region or the doped substrate is doped with the opposite type of dopant to the dopant or dopants of the one or more island photodiode regions.

9. The island photodiode as claimed in claim 1, wherein each carrier collection region comprises a corresponding doped well region of the semiconductor chip formed in a larger doped well region or a doped substrate of the semiconductor chip, wherein the larger doped well region or the doped substrate is doped with the opposite type of dopant to the dopant or dopants of the one or more carrier collection regions.

10. The island photodiode as claimed in claim 1, comprising one or more electrically conductive gates, each gate being electrically isolated from a semiconductor material of the semiconductor chip by a layer of electrically insulating material, wherein application of a suitable voltage to one or more of the gates creates one or more of the corresponding carrier collection regions in the semiconductor material of the semiconductor chip in one or more regions of the semiconductor chip underlying the one or more gates.

11. The island photodiode as claimed in claim 10, wherein each electrically conductive gate comprises, or is formed from, polysilicon.

12. The island photodiode as claimed in claim 10, wherein the voltage is selected to create a neutral region or an accumulated region in the one or more corresponding carrier collection regions in the semiconductor material of the semiconductor chip in the one or more regions of the semiconductor chip underlying the one or more gates so as to configure the one or more corresponding carrier collection regions into a non-collecting state or wherein the voltage is selected to create an inverted region or a depletion region in the one or more corresponding carrier collection regions in the semiconductor material of the semiconductor chip in the one or more regions of the semiconductor chip underlying the one or more gates so as to configure the one or more corresponding carrier collection regions into a collecting state.

13. The island photodiode as claimed in claim 10, wherein the one or more electrically conductive gates include a gate grid which extends across the light receiving area, wherein the gate grid defines one or more grid areas, and wherein each island photodiode region is located in a corresponding grid area.

14. The island photodiode as claimed in claim 10, wherein the one or more carrier collection regions include a carrier collection guard ring region which is arranged around the one or more island photodiode regions.

15. The island photodiode as claimed in claim 14, wherein the carrier collection guard ring region comprises a corresponding doped well region of the semiconductor chip formed in a larger doped well region or a doped substrate of the semiconductor chip, wherein the larger doped well region or the doped substrate is doped with the opposite type of dopant to the dopant or dopants of the carrier collection guard ring region.

16. The island photodiode as claimed in claim 15, wherein each portion of the gate grid extends from a position overlying one point on a perimeter of the carrier collection guard ring region to a position overlying another point on the perimeter of the carrier collection guard ring region and/or wherein one or more portions of the gate grid extend to a position overlying one or more of the island photodiode regions.

17. An electronic device comprising an island photodiode as claimed in claim 1, and a display, wherein the island photodiode is located behind the display and the island photodiode is configured to receive light through the display from a scene located in front of the display and, optionally, wherein the display comprises an OLED display.

18. A method of operating an island photodiode as claimed in claim 1, the method comprising:
exposing the light receiving area to first light during a first time period so as to generate carriers in the light receiving area, and collecting, in the one or more carrier collection regions, at least some of the carriers generated in the light receiving area during the first time period so as to cause the collected carriers to flow around a first circuit which includes the one or more carrier collection regions and first external circuitry during the first time period;
interrupting the collection of carriers in the one or more carrier collection regions and exposing the light receiving area to second light during a second time period so as to generate carriers in the light receiving area;
collecting, in the one or more island photodiode regions, at least some of the carriers generated in the light receiving area during the second time period so as to cause a photocurrent to flow around a second circuit which includes the one or more island photodiode regions and second external circuitry during the second time period; and
using the second external circuitry to determine an intensity of the second light incident on the light receiving area during a measurement time period based on a measurement of a quantity representative of the photocurrent flowing around the second circuit through the one or more island photodiode regions during the measurement time period, wherein the measurement time period occurs during the second time period or the measurement time period coincides with the second time period.

19. The method of claim 18, wherein the first light comprises light leakage, for example light leakage from the back side of a display such as an OLED display and, optionally, wherein the second light comprises ambient light such as light from a scene located in front of the display.

20. The method of claim 18, wherein the measurement time period occurs during the second time period and wherein a start time of the measurement time period is delayed by a predetermined delay from a start time of the second time period.
